(19) United States
(12) Patent Application Publication
(10) Pub. No.: US 2024/0249950 A1
(43) Pub. Date: Jul. 25, 2024

(54) SEMICONDUCTOR CHIP WITH VARYING THICKNESS PROFILE

(71) Applicant: Western Digital Technologies, Inc., San Jose, CA (US)

(72) Inventors: Yangming Liu, Shanghai (CN); Bo Yang, Dublin, CA (US); Ning Ye, San Jose, CA (US)

(21) Appl. No.: 18/449,452

(22) Filed: Aug. 14, 2023

Related U.S. Application Data
(60) Provisional application No. 63/481,453, filed on Jan. 25, 2023.

(51) Int. Cl. H01L 21/3065; H01L 21/82; H01L 23/00

(52) U.S. Cl. CPC H01L 21/3065; H01L 21/82; H01L 24/13; H01L 24/16; H01L 24/81; H01L 2224/13005; H01L 2224/13147; H01L 2224/16225; H01L 2224/8121; H01L 2924/20641

(57) ABSTRACT

Approaches directed at increasing the production yield of integrated circuits including layers of low-k dielectrics. One example provides a flip-chip assembly including a semiconductor chip attached to a substrate using pillars or bumps. The semiconductor chip has a thickness profile such that the chip is thinner near the corners than in middle portions. The thinner corner portions beneficially alleviate chip-integrity issues related to the stresses generated during the solder reflow operation while the thicker middle portions beneficially alleviate chip-integrity issues related to the stresses generated during the chip or die pick-up operation. Due to the alleviation of both types of chip-integrity issues, the number of instances in which the low-k dielectrics crack during the corresponding assembly operations is significantly reduced, thereby beneficially increasing the manufacturing yield.

### CROSS-REFERENCE TO RELATED APPLICATION

This application claims priority to and the benefit of U.S. Provisional Patent Application No. 63/481,453, filed on Jan. 25, 2023, the entire contents of which is incorporated herein by reference.

### FIELD

This application relates generally to integrated circuits, and more particularly but not exclusively, to preserving structural integrity of semiconductor dies having low-k dielectric layers.

### BACKGROUND

In semiconductor fabrication, a low-k material is a material with a small dielectric constant (k) relative to that of silicon dioxide. The use of low-k dielectric materials is one of several strategies directed at continued scaling of microelectronic devices. For example, in digital circuits, insulating dielectrics separate conducting parts, such as metal interconnects and transistors, from one another. As components have scaled and transistors have gotten closer together, the insulating dielectrics have thinned to the point where charge build up and crosstalk can adversely affect the performance of the device. Replacing the conventionally used silicon dioxide with a low-k dielectric of the same thickness typically reduces parasitic capacitance, thereby enabling faster switching speeds and lower heat dissipation.

### SUMMARY

Disclosed herein are approaches directed at increasing the production yield of integrated circuits (ICs) including layers of low-k dielectrics. One example provides a flip-chip (FC) assembly including a semiconductor chip attached to a substrate using conductive pillars or bumps. The semiconductor chip has a thickness profile according to which the semiconductor chip is thinner near the corners thereof than in middle portions thereof. The thinner corner portions of the semiconductor chip beneficially alleviate chip-integrity issues related to the stresses generated during the solder reflow operation while the thicker middle portions of the semiconductor chip beneficially alleviate chip-integrity issues related to the stresses generated during the chip pick-up operation. Due to the alleviation of both types of chip-integrity issues, the number of instances in which the low-k dielectrics crack during the corresponding manufacturing operations is significantly reduced, thereby beneficially increasing the IC manufacturing yield.

According to an example embodiment, provided is a flip-chip assembly, comprising: a substrate; and a semiconductor chip attached and electrically connected to the substrate with a plurality of conductive bumps, the semiconductor chip including at least one low-k dielectric layer adjacent to a device layer and a metal interconnect layer thereof, a middle portion of the semiconductor chip having a first thickness, a corner portion of the semiconductor chip having a smaller second thickness, wherein the plurality of conductive bumps includes a first set of bumps vertically between the middle portion of the semiconductor chip and the substrate, and a second set of bumps vertically between the corner portion of the semiconductor chip and the substrate.

According to another example embodiment, provided is a method of assembling an integrated circuit chip, wherein the chip includes electrical circuitry formed on a semiconductor wafer, at least one low-k dielectric layer adjacent to a device layer, and a metal interconnect layer, the method comprising thinning the semiconductor wafer to cause each instance of the chip to have a middle portion of a first thickness and a corner portion of a smaller second thickness.

In some embodiments, the method further comprises: separating diced instances of the chip from a holding tape by vertically pushing, with one or more ejector pins, on a first main surface of the chip and vertically applying suction, with a vacuum pick-up head, to an opposite second main surface of the chip, the one or more ejector pins pushing on the first main surface of the chip in the middle portion thereof; and reflowing a plurality of bumps in a reflow oven to attach and electrically connect the chip to a substrate, the plurality of bumps including a first set of solder bumps vertically between the middle portion of the chip and the substrate and a second set of bumps vertically between the corner portion of the chip and the substrate.

According to yet another example embodiment, provided is a semiconductor chip, comprising: a device layer; a metal interconnect layer; and at least one low-k dielectric layer adjacent to the device layer and to the metal interconnect layer, wherein a middle portion of the semiconductor chip has a first thickness, and a corner portion of the semiconductor chip has a smaller second thickness.

### BRIEF DESCRIPTION OF THE DRAWINGS

FIGS. 1A-1C schematically illustrate a top view and cross-sectional side views of an FC assembly according to example embodiments.

FIG. 2 schematically illustrates a side view of a portion of the chip used in the FC assembly of FIGS. 1A-1C according to an embodiment.

FIG. 3 is a flowchart illustrating a manufacturing method that can be used to make the FC assembly of FIGS. 1A-1C according to an embodiment.

FIG. 4 is a block diagram illustrating a chip pick-up operation of the manufacturing method of FIG. 3 according to an embodiment.

FIG. 5 graphically illustrates stresses experienced by the chip used in the FC assembly of FIGS. 1A-1C during the chip pick-up operation illustrated in FIG. 4 according to an example.

FIGS. 6A-6B graphically illustrate stresses experienced by the chip used in the FC assembly of FIGS. 1A-1C during a solder-reflow operation of the manufacturing method of

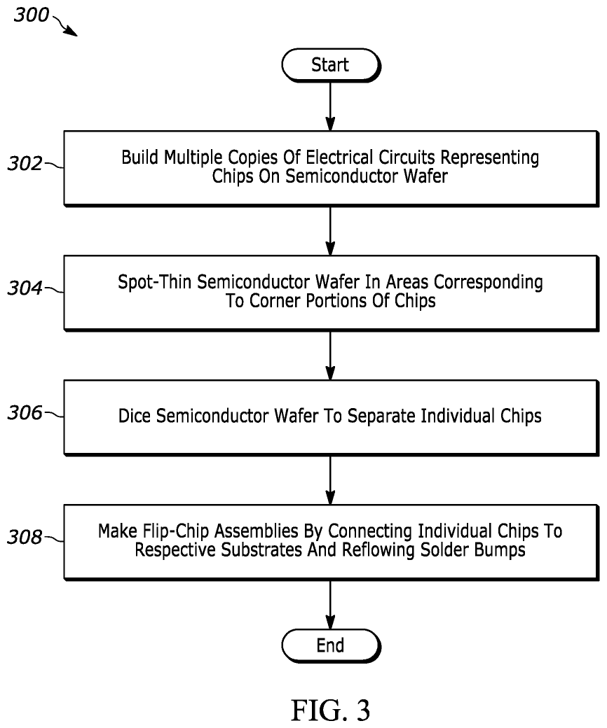

FIG. 3 according to an example.

### DETAILED DESCRIPTION

In the following description, numerous details are set forth, such as data storage device configurations, controller operations, and the like, in order to provide an understanding of one or more aspects of the present disclosure. It will be readily apparent to one skilled in the art that these specific details are merely exemplary and not intended to limit the scope of this application. The following description is intended solely to give a general idea of various aspects of the present disclosure and does not limit the scope of the disclosure in any way.

One challenge associated with the use of low-k dielectrics in semiconductor manufacturing is due to the low-k dielectrics relatively weak mechanical characteristics. For example, some low-k dielectrics are about ten times worse than silicon dioxide in various categories of thermo-mechanical strength. As a result, a typical failure mode during flip-chip packaging includes the low-k dielectrics cracking due to significant mechanical loads typically experienced by the chip in some packaging operations.

For example, when a flip-chip die is being attached to the corresponding substrate through reflow soldering, relatively high stresses are generated at the die due to high temperature gradients and a typically present coefficient of thermal expansion (CTE) mismatch between different die layers and between the die and substrate. Typically, the larger is the thickness of the die, the higher is the local stress generated through this CTE-mismatch (first) mechanism. In contrast, when the flip-chip die is picked up from the corresponding wafer, an ejecting needle typically pushes on the die at the underside, thereby causing relatively high stresses to be generated near the area of contact. Typically, the larger is the thickness of the die, the lower is the local stress generated through the latter (second) mechanism. Both the first and second mechanisms can disadvantageously cause the low-k dielectrics in some dies to crack during the corresponding packaging operations, thereby rendering those dies unusable.

The above indicated problems can beneficially be addressed using at least some embodiments disclosed herein. Through experimentation and computer simulation, the inventors realized that the above-mentioned first mechanism typically causes higher local stresses to be generated near the die's corner solder bumps, whereas the above-mentioned second mechanism typically causes higher stresses to be generated in the middle portions of the die. The inventors thus concluded that the conflicting die-thickness constraints presented by the first and second mechanisms can be balanced out by creating a thickness profile according to which the die is thinner near the corners thereof than in the middle portions thereof. As a result, the thinner corner portions of the die can beneficially alleviate the die-integrity issues related to the local stresses generated through the first mechanism while the thicker middle portions of the die can beneficially alleviate the die-integrity issues related to the local stresses generated through the second mechanism. Due to the reduction of both types of local stresses, the number of instances in which the low-k dielectrics crack during the corresponding die packaging operations is significantly reduced, thereby beneficially increasing the IC manufacturing yield.

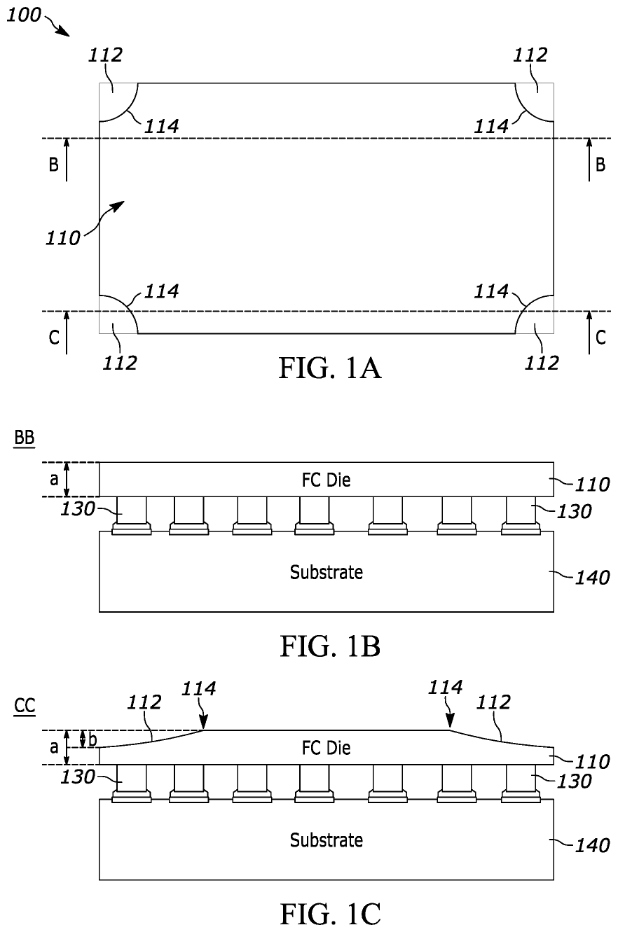

FIGS. 1A-1C schematically illustrate a top (plan) view and cross-sectional side views of a flip-chip (FC) assembly 100 according to an embodiment. More specifically, FIG. 1A shows a top view of the FC assembly 100. FIGS. 1B-1C show cross-sectional side views of the FC assembly 100 along cross-sectional planes BB and CC, respectively. Positions of the cross-sectional planes BB and CC in the plan view of the FC assembly 100 are indicated by dashed lines in FIG. 1A.

The FC assembly 100 includes a semiconductor chip (die) 110 and a substrate 140 electrically and structurally connected by a plurality of pillars or bumps 130. In an example fabrication process, a large number of the semiconductor chips 110 is formed on a single semiconductor wafer. The individual semiconductor chips 110 are patterned with small conducting pads that provide electrical connections to external circuits, such as the substrate 140. A respective pillar or bump 130 is formed on each conducting pad. The semiconductor chips 110 are then cut out of the wafer in a process called dicing. To attach a semiconductor chip 110 to a corresponding substrate 140, the semiconductor chip 110 is inverted to bring the bumps 130 down onto matching electrical connectors (e.g., contact pads) of the substrate 140. Solder caps of the bumps 130 are then melted via a reflow process to produce permanent electrical connections between the semiconductor chip 110 and the substrate 140. In various examples, the substrate 140 can be an interconnecting substrate, a redistribution layer, an interposer, a laminate plate, a printed wiring board, or the like. In additional examples, bumps 130 of various geometric shapes may also be used.

The semiconductor chip 110 has a non-uniform thickness. More specifically, middle portions of the semiconductor chip 110 have a constant thickness a as indicated in FIG. 1B. In contrast, corner portions 112 of the chip 110 are thinner than the middle portions thereof. In the example shown, each corner portion 112 has a varying thickness that gradually changes from the thickness a at an inner perimeter 114 of the corner portion 112 to the thickness (a−b) at the corresponding edges of the chip 110, where b<a. In additional examples, step-like thickness profiles are used. With a step-like thickness profile, the corresponding corner portion 112 has a constant thickness between the corresponding edges of the semiconductor chip 110 and the inner perimeter 114 of the corner portion 112. Along the inner perimeter 114 of the corner portion 112 the thickness of the semiconductor chip 110 changes in a step-like manner, e.g., has a step-like thickness change from the constant thickness (a−b) to the constant thickness a. In various examples, in the top view of the chip 110 (FIG. 1A), the total area of the corner portions 112 is smaller than about 5%, 10%, or 15% of the top surface area of the semiconductor chip 110 in the FC assembly 100.

In different examples, the inner perimeter 114 of an individual corner portion 112 has different shapes. Example shapes for implementing the inner perimeter 114 include a circular arc, an elliptical arc, a straight line, and a rectilinear shape. Example values of the thickness a are in the range between 0.2 mm and 0.4 mm. Example values of the relief thickness b are in the range between 0.02 mm and 0.2 mm. In some examples, a footprint of the corner portion 112 on a main surface of the semiconductor chip 110 has a polygonal shape.

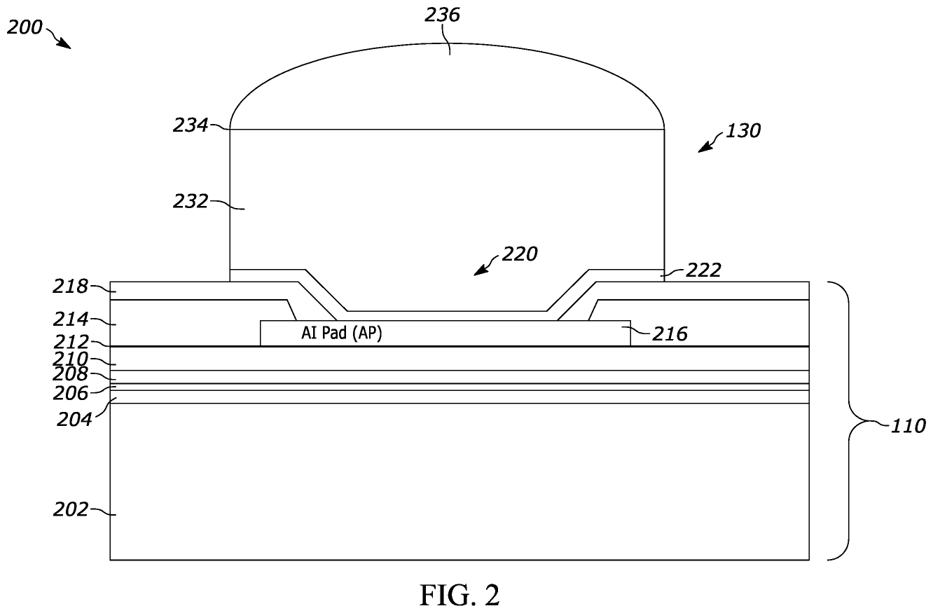

FIG. 2 schematically illustrates a portion 200 of the semiconductor chip 110 according to an embodiment. The portion 200 has one of the pillars or bumps 130, which is shown in FIG. 2 prior to the reflow process. The bump 130 includes a cylindrical stub (or pillar) 232 and a solder cap 236. The bump 130 also includes a barrier layer 234 sandwiched between the cylindrical stub 232 and the solder cap 236. During the reflow process, the solder cap 236 is melted, reflowed, and resolidified to create a corresponding permanent connection between the semiconductor chip 110 and the substrate 140. In some examples, the following materials are used to implement the bump 130: (i) copper (Cu) for the cylindrical stub (pillar) 232; (ii) nickel (Ni) for the barrier layer 234; and (iii) a tin-silver (Sn/Ag) alloy for the solder cap 236.

In the example shown, the semiconductor chip 110 includes a bulk (e.g., silicon, Si) layer 202, a device layer 204, a low-k dielectric layer 206, one or more metal interconnect layers 208, an insulator layer 210, a passivation layer 212, an insulator layer 214, and a polyimide layer 218. The device layer 204 includes various semiconductor devices, such as, transistors, diodes, resistors, etc., of the semiconductor chip 110. The low-k dielectric layer 206 provides electrical insulation between various semiconductor devices of the device layer 204 and conductors of the metal interconnect layers 208. The conductors of metal interconnect layers 208 are patterned to provide electrical connections between various semiconductor devices of the device layer 204 and further to provide electrical connections to surface bonding pads, such as a contact pad 216. In the example shown, the contact pad 216 is made of aluminum (Al). In other examples, other electrically conducting materials can also be used to implement the contact pad 216.

The insulator layer 210 vertically offsets the contact pad 216 from the top metal interconnect layer 208. The passivation layer 212 is used for improved manufacturability of the contact pad 216. The insulator layer 214 is used to laterally encapsulate the contact pads 216. In some examples, the insulator layers 210 and 214 comprise silicon dioxide or silicon oxynitride. The polyimide layer 218 serves as a stress buffer passivation layer that improves reliability by buffering stresses introduced during some packaging operations. In some cases, dielectric properties of the polyimide layer 218 are relied on to create additional layers of device interconnect beyond the wafer fab. An opening 220 in the layers 214, 218 provides access to the top surface of the contact pad 216. An under-bump metallization (UBM) layer 222 is deposited in the opening 220 for improved electrical conductivity at the corresponding interface. In various examples, the UBM layer 222 comprises titanium (Ti), copper (Cu), and/or nickel (Ni). The cylindrical stub 232 of the bump 130 is attached to the UBM layer 222 as indicated in FIG. 2.

Herein, the term “vertical” refers to a direction that is approximately orthogonal to a main plane of the semiconductor chip 110. The term “horizontal” refers to a direction that is approximately parallel to the main plane of the semiconductor chip 110. Herein, a “main plane” of an object, such as a chip (die), a substrate, an IC, or a printed circuit board is a plane parallel to a substantially planar surface thereof that has about the largest area among exterior surfaces of the object. This substantially planar surface may be referred to as a main surface. The exterior surfaces of the object that have one relatively large size, e.g., length, but are of much smaller area, e.g., less than one quarter of the main-surface area, are referred to as the edges of the object.

Due to the wide range of methods that can be used to form silicon dioxide layers in semiconductor manufacturing, silicon dioxide is used conventionally as the baseline to which other dielectrics are compared. The relative dielectric constant of silicon dioxide (SiO₂) is 3.9. In various examples, the dielectrics used to make the low-k dielectric layer 206 include, but are not limited to, organosilicate glass (OSG), porous silicon dioxide, porous OSG, spin-on organic polymers, spin-on silicon-based polymers, and amorphous carbon. In some additional examples, the low-k dielectric layer 206 can be implemented using air gaps.

FIG. 3 is a flowchart illustrating a manufacturing method 300 that can be used to make the FC assembly 100 according to an embodiment. The method 300 includes building multiple copies of the electrical circuits of the semiconductor chip 110 on a semiconductor wafer (in a block 302). In various examples, operations of the block 302 include a sequence of photolithographic and chemical processing steps during which the electrical circuits are gradually created. In one example, operations of the block 302 include: depositing passivation and insulator layers, such as the insulator layers 210, 214 and the passivation layer 212; forming contact pads, such as the contact pad 216; depositing polyimide and UBM layers, such as the polyimide layer 218 and the UBM layer 222.

The method 300 also includes spot-thinning the semiconductor wafer in areas corresponding to corner portions 112 of the nascent semiconductor chips 110 (in a block 304). In one example, the spot-thinning operation in the block 304 is performed after uniform thinning of the bulk semiconductor layer of the wafer down to the bulk layer 202. In various implementations, the spot-thinning operation in the block 304 can be performed via plasma etching, dry etching, beam etching, reactive ion etching, or other suitable thinning operations.

The method 300 also includes dicing the semiconductor wafer into individual semiconductor chips 110 (in a block 306). The semiconductor wafer is typically diced, in the block 306, on an adhesive tape so that the individual semiconductor chips 110 are contained but become removable from the wafer for subsequent bonding into respective FC assemblies 100. In one example, the individual semiconductor chips 110 are pushed from the adhesive tape, in the block 306, using one or more ejector pins and are picked up by a vacuum tool for further handling.

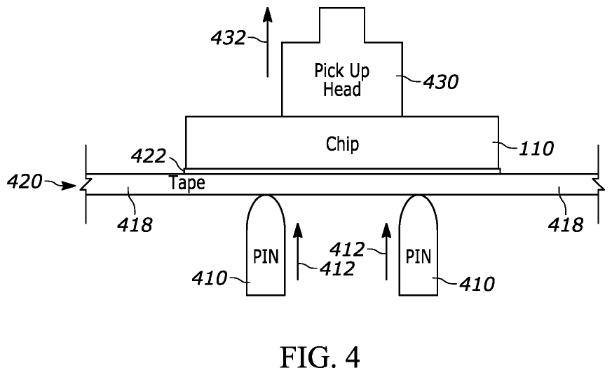

FIG. 4 is a schematic diagram illustrating a chip pick-up operation of the block 306 according to an example embodiment. After the dicing operation of the block 306, the semiconductor chip 110 remains attached, via a thin adhesive layer 422, to a flexible tape 420. A pick-up head 430 is placed on top of the semiconductor chip 110 and is operated to apply vacuum suction thereto. Ejection pins 410 are positioned under the tape 420 and start moving vertically as indicated in FIG. 4 by arrows 412. When the ejection pins 410 come into physical contact with the tape 420, a vertically directed mechanical force is applied, through the tape 420, to the chip 110. The sides 418 of the tape 420 are held in place while the pick-up head 430 moves up, as indicated by an arrow 432, at the same pace as the ejection pins 410, thereby causing the adhesive layer 422 to peel off and separating the chip 110 and the tape 420.

Referring back to FIG. 3, the method 300 further includes making the FC assembly 100 (in a block 308). In one example, operations of the block 308 include: (i) attaching a plurality of pillars or bumps 130 to the semiconductor chip 110, e.g., as indicated in FIG. 2; (ii) inverting (flipping) the orientation of the bumped semiconductor chip 110 to have the bumps face the substrate 140; (iii) aligning the bumps 130 with the corresponding contact pads on the substrate 140; and (iv) reflowing the solder material of the bumps 130 in a reflow oven to form the FC assembly 100 illustrated in FIGS. 1A-1C. In various examples, the FC assembly 100 produced in this manner undergoes further packaging operations in the block 308, such as underfilling, molding (using a suitable molding compound), baking, electroplating, and laser marking.

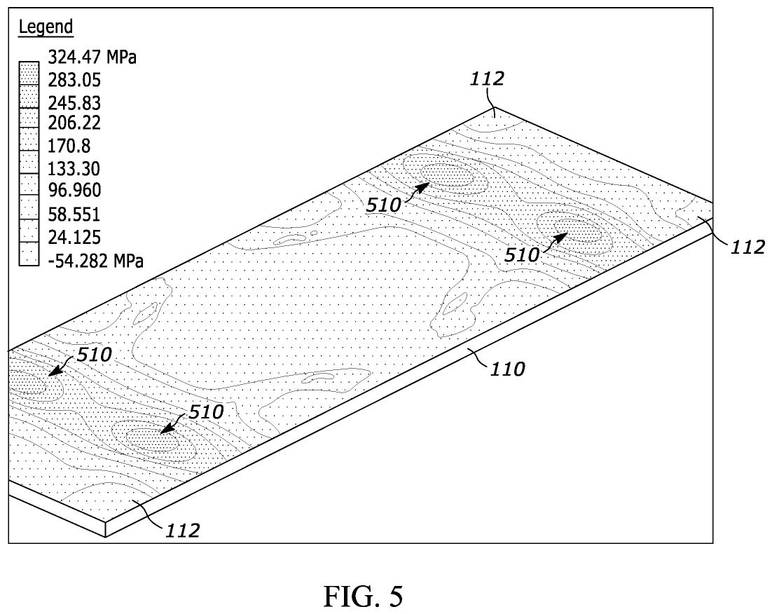

FIG. 5 graphically illustrates stresses experienced by the semiconductor chip 110 during the chip pick-up operation illustrated in FIG. 4 according to one example. In this example, four ejection pins 410 are used to separate the semiconductor chip 110 from the tape 420. Upon contact with the tape 420, the four pins 410 cause relatively high stresses to be generated in the corresponding four areas 510 of the chip 110. The stress areas 510 are located in respective middle portions of the semiconductor chip 110 and relatively far from the thinned corners 112 of the semiconductor chip 110. Since the semiconductor chip 110 has the larger thickness a in the stress areas 510 (also see FIG. 1B), the probability of structural damage to the semiconductor chip 110 in the stress areas 510 is relatively low.

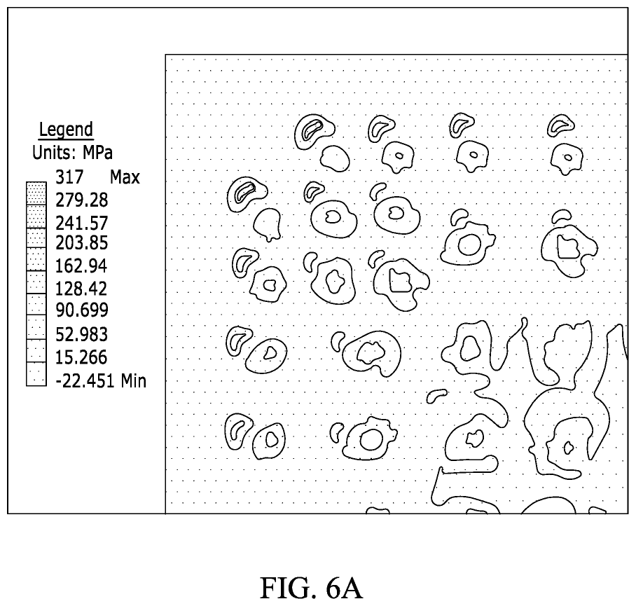

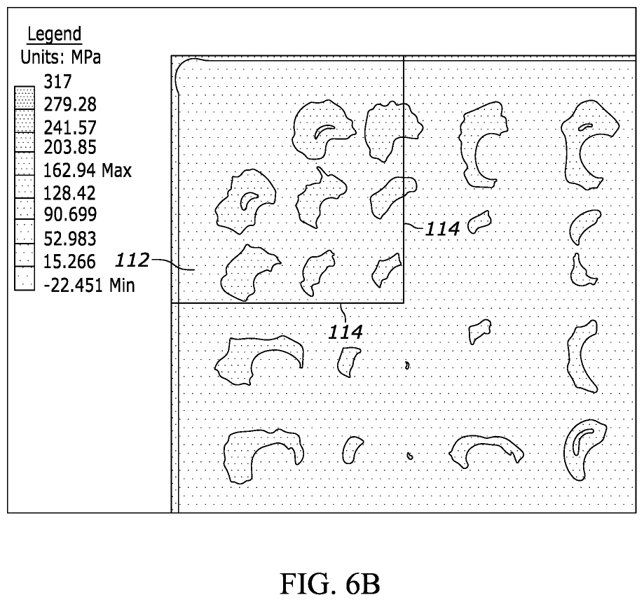

FIGS. 6A-6B graphically illustrate stresses experienced by the semiconductor chip 110 during the solder-reflow operation of the block 308 of the manufacturing method 300 according to one example. More specifically, FIG. 6A graphically shows the stresses generated during the solder-reflow operation in a conventional semiconductor chip having a uniform thickness a=0.25 mm across the entire chip. FIG. 6B similarly graphically shows the stresses generated during the solder-reflow operation in the semiconductor chip 110 for which a=0.25 mm and b=0.15 mm (also see FIG. 1C). In the example shown in FIG. 6B, the corner portion 112 has a rectangular shape, with the inner perimeter 114 thereof being indicated by a correspondingly labeled solid line. There are eight solder bumps 130 located vertically under the rectangular corner portion 112. There are twelve additional pillars or bumps 130 in the part of the semiconductor chip 110 depicted in FIG. 6B, with those twelve additional bumps 130 being located vertically outside the inner perimeter 114 of the rectangular corner portion 112. The conventional semiconductor chip illustrated in FIG. 6A has the same layout of the bumps 130 as the semiconductor chip 110 illustrated in FIG. 6B.

Comparison of the stress profiles shown in FIGS. 6A and 6B reveals significant reduction of the reflow-related stresses in the semiconductor chip 110 with respect to the stresses in the conventional semiconductor chip. For example, the low-k dielectric layer 206 of the semiconductor chip 110 illustrated in FIG. 6B experiences maximum reflow stresses of approximately 163 MPa. In contrast, the low-k dielectric layer 206 of the conventional semiconductor chip illustrated in FIG. 6A experiences maximum reflow stresses of approximately 317 MPa. Since the stresses in the low-k dielectric layer 206 of the semiconductor chip 110 are reduced approximately by a factor of two, the probability of structural damage to the low-k dielectric layer 206 of the semiconductor chip 110 during the reflow operation is beneficially reduced as well.

With regard to the processes, systems, methods, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain implementations and should in no way be construed to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

Unless explicitly stated otherwise, each numerical value and range should be interpreted as being approximate as if the word “about” or “approximately” preceded the value or range.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Unless otherwise specified herein, in addition to its plain meaning, the conjunction “if” may also or alternatively be construed to mean “when” or “upon” or “in response to determining” or “in response to detecting,” which construal may depend on the corresponding specific context. For example, the phrase “if it is determined” or “if [a stated condition] is detected” may be construed to mean “upon determining” or “in response to determining” or “upon detecting [the stated condition or event]” or “in response to detecting [the stated condition or event].”

Throughout the detailed description, the drawings, which are not to scale, are illustrative only and are used in order to explain, rather than limit the disclosure. The use of terms such as height, length, width, top, bottom, is strictly to facilitate the description of the embodiments and is not intended to limit the embodiments to a specific orientation. For example, height does not imply only a vertical rise limitation, but is used to identify one of the three dimensions of a three-dimensional structure as shown in the figures. Such “height” would be vertical where the layers are horizontal but would be horizontal where the layers are vertical, and so on. Similarly, while all figures show the different layers as horizontal layers such orientation is for descriptive purpose only and not to be construed as a limitation.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. The same type of distinction applies to the use of terms “attached” and “directly attached,” as applied to a description of a physical structure. For example, a relatively thin layer of adhesive or other suitable binder can be used to implement such “direct attachment” of the two corresponding components in such physical structure.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

As used in this application, the terms “circuit” and “circuitry” may refer to one or more or all of the following: (a) hardware-only circuit implementations (such as implementations in only analog and/or digital circuitry); (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions); and (c) hardware circuit(s) and or processor(s), such as a microprocessor(s) or a portion of a microprocessor(s), that requires software (e.g., firmware) for operation, but the software may not be present when it is not needed for operation.” This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

“SUMMARY” in this specification is intended to introduce some example embodiments, with additional embodiments being described in “DETAILED DESCRIPTION” and/or in reference to one or more drawings. “SUMMARY” is not intended to identify essential elements or features of the claimed subject matter, nor is it intended to limit the scope of the claimed subject matter.

“ABSTRACT” is provided to allow the reader to quickly ascertain the nature of the technical disclosure. It is submitted with the understanding that it will not be used to interpret or limit the scope or meaning of the claims. In addition, in the foregoing “DETAILED DESCRIPTION,” it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into “DETAILED DESCRIPTION,” with each claim standing on its own as a separately claimed subject matter.

What is claimed is:

1. A flip-chip assembly, comprising:
a substrate; and
a semiconductor chip attached and electrically connected to the substrate with a plurality of conductive bumps, the semiconductor chip including at least one low-k dielectric layer adjacent to a device layer and to a metal interconnect layer thereof, a middle portion of the semiconductor chip having a first thickness, a corner portion of the semiconductor chip having a smaller second thickness,
wherein the plurality of conductive bumps includes a first set of bumps vertically between the middle portion of the semiconductor chip and the substrate, and a second set of bumps vertically between the corner portion of the semiconductor chip and the substrate.

2. The flip-chip assembly of claim 1, wherein the corner portion of the semiconductor chip has a varying thickness that gradually changes from the first thickness at an inner perimeter of the corner portion to the smaller second thickness at an edge of the semiconductor chip.

3. The flip-chip assembly of claim 1,
wherein the corner portion of the semiconductor chip has a constant thickness, the constant thickness being the smaller second thickness; and
wherein the semiconductor chip has a step-like thickness change at an inner perimeter of the corner portion from the smaller second thickness to the first thickness.

4. The flip-chip assembly of claim 1, wherein an inner perimeter of the corner portion has a shape of a circular or elliptical arc.

5. The flip-chip assembly of claim 1, wherein a footprint of the corner portion on a main surface of the semiconductor chip has a polygonal shape.

6. The flip-chip assembly of claim 1, wherein the semiconductor chip has a rectangular shape that includes four instances of the corner portion.

7. The flip-chip assembly of claim 1, wherein a bump of the plurality of conductive bumps comprises:
a cylindrical stub directly attached to the semiconductor chip;
a reflowed solder cap directly attached to the substrate; and
a barrier layer sandwiched between the cylindrical stub and the reflowed solder cap.

8. The flip-chip assembly of claim 1, wherein a difference between the first thickness and the smaller second thickness is in a range between 0.02 mm and 0.2 mm.

9. A method of assembling an integrated circuit chip, wherein the chip includes electrical circuitry formed on a semiconductor wafer, at least one low-k dielectric layer adjacent to a device layer, and a metal interconnect layer, the method comprising: thinning the semiconductor wafer to cause each instance of the chip to have a middle portion of a first thickness and a corner portion of a smaller second thickness.

10. The method of claim 9, further comprising:
separating diced instances of the chip from a holding tape by vertically pushing, with one or more ejector pins, on a first main surface of the chip and vertically applying suction, with a vacuum pick-up head, to an opposite second main surface of the chip, the one or more ejector pins pushing on the first main surface of the chip in the middle portion thereof; and
reflowing a plurality of bumps in a reflow oven to attach and electrically connect the chip to a substrate, the plurality of bumps including a first set of solder bumps vertically between the middle portion of the chip and the substrate and a second set of bumps vertically between the corner portion of the chip and the substrate.

11. The method of claim 9, wherein the thinning is performed via plasma etching, dry etching, beam etching, or reactive ion etching to cause the corner portion of the chip to have a varying thickness that gradually changes from the first thickness at an inner perimeter of the corner portion to the smaller second thickness at an edge of the chip.

12. The method of claim 9, wherein the thinning is performed to cause the chip to have a step-like thickness change at an inner perimeter of the corner portion from the smaller second thickness to the first thickness.

13. The method of claim 9, wherein the thinning is performed to cause an inner perimeter of the corner portion to have a shape of a circular or elliptical arc.

14. The method of claim 9, wherein the thinning is performed to cause a footprint of the corner portion on a main surface of the chip to have a polygonal shape.

15. The method of claim 9, wherein a difference between the first thickness and the smaller second thickness is in a range between 0.02 mm and 0.2 mm.

16. A semiconductor chip, comprising:
a device layer;
a metal interconnect layer; and
at least one low-k dielectric layer adjacent to the device layer and to the metal interconnect layer,
wherein a middle portion of the semiconductor chip has a first thickness, and a corner portion of the semiconductor chip has a smaller second thickness.

17. The semiconductor chip of claim 16, further comprising:
a first set of conductive bumps formed on a first set of bonding pads of the semiconductor chip and disposed vertically proximate to the middle portion of the semiconductor chip; and
a second set of conductive bumps formed on a second set of bonding pads and disposed vertically proximate to the corner portion of the semiconductor chip.

18. The semiconductor chip of claim 17, wherein the conductive bumps comprise copper pillars.

19. The semiconductor chip of claim 16, wherein the corner portion of the semiconductor chip has a varying thickness that gradually changes from the first thickness at an inner perimeter of the corner portion to the smaller second thickness at an edge of the semiconductor chip.

20. The semiconductor chip of claim 16, wherein the corner portion of the semiconductor chip has a constant thickness, the constant thickness being the smaller second thickness, and the semiconductor chip has a step-like thickness change at an inner perimeter of the corner portion from the smaller second thickness to the first thickness.
